(19) United States
(12) Patent Application Publication
(10) Pub. No.: US 2016/0244605 A1
(43) Pub. Date: Aug. 25, 2016

(54) RESIN COMPOSITION AND PRINTED CIRCUIT BOARD COMPRISING THE SAME

(71) Applicant: Samsung Electro-Mechanics Co., Ltd., Suwon-si (KR)

(72) Inventors: Ki-Seok KIM, Incheon (KR); Ji-Hye SHIM, Suwon-si (KR); Hyung-Mi JUNG, Suwon-si (KR); Ji-Eun WOO, Seoul (KR)

(73) Assignee: Samsung Electro-Mechanics Co., Ltd., Suwon-si (KR)

(21) Appl. No.: 15/050,360

(22) Filed: Feb. 22, 2016

(30) Foreign Application Priority Data
Feb. 23, 2015 (KR) 10-2015-0025183

(51) Int. Cl. C08L 63/00; H05K 1/11; H05K 1/03

(52) U.S. Cl. CPC C08L 63/00; H05K 1/0373; H05K 1/115

(57) ABSTRACT

A resin composition and a printed circuit board comprising the same, include an epoxy resin, and a teflon resin including nano-silica on a surface thereof.

### CROSS REFERENCE TO RELATED APPLICATION

This application claims the benefit under 35 USC 119(a) of Korean Patent Application No. 10-2015-0025183, filed on Feb. 23, 2015, the entire disclosure of which is hereby incorporated by reference for all purposes.

### BACKGROUND

1. Field

The following description relates to a resin composition and a printed circuit board including the same.

2. Description of Related Art

A board on which an electronic circuit is printed is used in various electronic products such as computers, semiconductors, displays, communications devices, and other similar electronic devices. The board may include signal lines to transfer signals, insulating layers to prevent short-circuits between the signal lines, and a switching element.

Thus, there is a continuous demand for high density circuit boards in view of developments in compact electronic devices that operate at higher frequencies and are digitalized.

A printed circuit board may be formed by laminating a prepreg in which glass cloth is impregnated with an epoxy resin. The printed circuit board is semi-hardened on an inner-layer circuit board including a circuit formed thereon.

Alternatively, the printed circuit board is formed by a build-up method of alternatively laminating an insulating layer on a circuit pattern of an inner-layer circuit board, including a circuit formed thereon. In the build-up method, via holes are formed by laser processing, such that signal line density is increased.

In accordance with the development of electronic devices, such printed circuit boards have gradually been lightened, thinned, and miniaturized, while considerations of electrical, thermal, and mechanical stability in such boards have increased in importance for the stability and reliability of electronic devices.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In accordance with an embodiment, there is provided a resin composition, including: an epoxy resin; and a teflon resin including nano-silica on a surface thereof.

The teflon resin may include a particle size of 5.0 μm or less.

The nano-silica may include a particle size of 10 nm or less.

An amount of the teflon resin may be 20 wt % to 50 wt %, based on a total weight of the resin composition.

The resin composition may also include a silica filler.

An amount of the silica filler may be 5 wt % to 20 wt %, based on a total weight of the resin composition.

An insulating layer may include the epoxy resin and the teflon resin may include a dissipation factor of 0.0050 tangent δ or less.

An insulating layer may include the epoxy resin and the teflon resin may include a dissipation factor of 0.0040 tangent δ or less.

The resin composition may also include an ester hardening agent.

In accordance with an embodiment, there is provided a printed circuit board, including: an insulating layer including an epoxy resin, and a teflon resin including nano-silica on a surface thereof.

The insulating layer may include a dissipation factor of 0.0050 tangent δ or less.

The insulating layer may include a dissipation factor of 0.0040 tangent δ or less.

The teflon resin may include a particle size of 5.0 μm or less.

The nano-silica may include a particle size of 10 nm or less.

An amount of the teflon resin may be 20 wt % to 50 wt %, based on a total weight of the resin composition.

The printed circuit board may also include a silica filler.

In accordance with an embodiment, there is provided a printed circuit board, including: a first insulating layer formed as a center layer; a second insulating layer formed on an upper surface of the first insulating layer; a third insulating layer formed on a lower surface of the first insulating layer; a horizontal signal line; and a via electrode, wherein the horizontal signal line and the via electrode are formed on at least one surface of the first insulating layer, the second insulating layer, and the third insulating layer, the via electrode vertically passes through the insulating layers to electrically connect each horizontal signal line, and at least one of the first insulating layer, the second insulating layer, and the third insulating layer may include an epoxy resin and a teflon resin including nano-silica on a surface thereof.

The teflon resin may include a particle size of 5.0 μm or less.

The nano-silica may include a particle size of 10 nm or less.

An amount of the teflon resin may be 20 wt % to 50 wt %, based on a total weight of the resin composition.

Other features and aspects will be apparent from the following detailed description, the drawings, and the claims.

### BRIEF DESCRIPTION OF THE DRAWINGS

FIG. 1 is a conceptual view illustrating a resin composition according to an embodiment of the present disclosure.

FIG. 2 is a conceptual view illustrating a resin composition according to another embodiment of the present disclosure.

FIG. 3 is a sectional view schematically illustrating a printed circuit board according to an embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

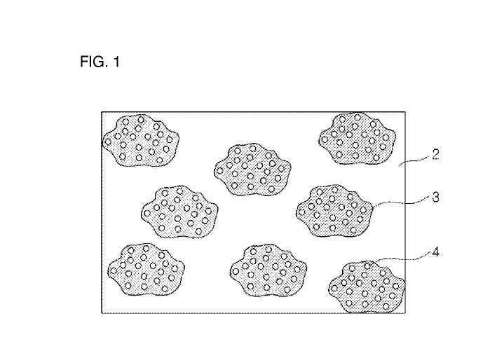

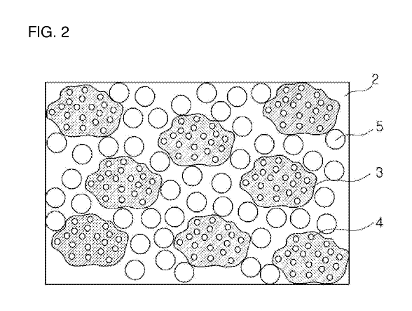

FIG. 1 and FIG. 2 are conceptual view illustrating a resin composition according to an embodiment.

Referring to FIG. 1 and FIG. 2, a resin composition, according to an embodiment, includes an epoxy resin 2 and a teflon(polytetrafluoroethylene, PTFE) resin 3. The teflon resin includes nano-silica 4 on the surface.

A polymer filler included in the resin composition is configured to have a high miscibility and dispersibility with the epoxy resin because optimal properties of the resin composition are obtainable when the polymer filler is dispersed evenly in the resin composition.

In a general resin composition, surface energy of the polymer filler is not high enough to have good miscibility and dispersibility with the epoxy resin. When the resin composition does not have enough polymer filler, a dissipation factor in the resin composition is high. Conventionally, the polymer filler is added to an amount of 70 wt % or more in a resin composition to resolve this problem. However, when the amount of polymer filler is high in the resin composition, the polymer filler remains on the surface of an insulating layer made of the resin composition. As a result, an adhesion between the insulating layer and the conductive circuit, which is formed on the surface of the insulating layer, deteriorates causing delamination of the conductive circuit from the insulating layer.

The teflon resin 3, which includes the nano-silica 4 on a surface thereof, is used as the polymer filler for the resin composition, according to an embodiment. The surface of the teflon resin 3 has a high surface energy due to the nano-silica 4. As a result, the teflon resin 3 has a high miscibility and dispersibility with the epoxy resin 2. Even though 50 wt % or less of the teflon resin 3 is used in the resin composition, the teflon resin 3 provides sufficient miscibility and dispersibility to improve the adhesion between the insulating layer, which is manufactured using the resin composition, and the conductive circuit. Because the resin composition includes the polymer filler having low dissipation factor, the insulating layer, which is manufactured using the resin composition, also has a low dissipation factor.

The teflon resin 3 used in the embodiment may be a pallet typed teflon resin including polytetrafluoroethylene (C₂F₄), but it is not limited thereto. Other teflon resins may be used as the teflon resin 3 including the nano-silica 4.

In one embodiment, the teflon resin 3 is formed by surface-treatment using hot-melt mixing with the nano-silica 4. The teflon resin 3 is crushed and processed to provide the resin composition including the nano-silica 4 on the surface. Such forming method is an example and other forming methods may be used.

An example of the epoxy resin 2 used in an embodiment includes a phenol-based glycidyl ether epoxy resin, such as a phenol novolac type epoxy resin, a cresol novolac type epoxy resin, an o-cresol novolac type epoxy resin, a naphthol modified novolac type epoxy resin, a bisphenol A type epoxy resin, a bisphenol F type epoxy resin, a biphenyl type epoxy resin, a triphenyl type epoxy resin and the like; a dicyclopentadiene type epoxy resin including a dicyclopentadiene backbone; a naphthalene type epoxy resin including a naphthalene backbone; dihydroxy benzopyran type epoxy resin; a glycidylamine type epoxy resin of which a raw material is a polyamine such as a diaminophenyl methane; a triphenol methane type epoxy resin; a tetraphenyl ethane type epoxy resin; and a mixture thereof but it may not be limited thereto.

For instance, the epoxy resin 2 may be N,N,N′,N′-tetraglycidyl-4,4′-methylenebisbenzenamine, polyglycidyl ether of o-cresol-formaldehyde novolac, or a mixture thereof.

In an embodiment, a filler used is the teflon resin 3 and includes the nano-silica 4 on the surface. In one illustrative example, the teflon resin 3 has a particle size of 5.0 μm. However, a person skilled in the art will appreciate that the teflon resin 3 may have various particle sizes such as less than 5 μm.

When the particle size of the teflon resin 3 is less than 0.5 μm, a specific surface area thereof increases causing a decrease of adhesion with a metal foil, which is formed on the surface of the insulating layer and the conductive circuit due to difficulties in filling. On the other hand, when the particle size of the teflon resin 3 is greater than 5.0 μm, the particle size of the teflon resin 3 becomes too large to provide good dispersibility and miscibility. As a result, a decrease of adhesion occurs between the conductive circuit board and the insulating layer due to residue of the teflon resin 3 on the surface of the insulating layer. When the particle size of the teflon resin 3 is 3.0 μm or less, the teflon resin 3 enables an effective dispersibility, miscibility, and adhesion between the conductive circuit and the insulating layer. Thus, the particle size of the teflon resin 3 may be 5.0 pm or less, for example, 0.5 μm to 5.0 μm, or 0.5 μm to 3.0 μm.

Adhesion, dispersibility, and miscibility depending on a particle size of the teflon resin 3 is summarized in Table 1, reproduced below. Table 1 illustrates results based on an epoxy resin including a bisphenol A type epoxy resin and an o-cresol novolac type(o-cresol novolac) epoxy resin mixed in 1:1 used and an active ester(HPC-8000-65T, DIC Corp.) used as a hardening agent. The epoxy resin and the hardening agent were mixed in an equivalent ratio of 1:1. A teflon resin 3 having a particle size of particle size 0.2, 0.3, 0.5, 2, 3, 5, 7μm was used as a filler. The teflon resin 3 was used in an amount of 50 wt % when a total amount of the epoxy resin and the hardening agent is 100 wt %. A pallet-typed teflon resin 3 including polytetrafluoroethylene (C₂F₄) was used.

Dispersibility is determined based on filler sedimentation time and degassing stability. Filler sedimentation time is a time at which layers of a resin composition are delaminated due to filler sedimentation when the resin composition, including the teflon resin 3, is placed at room temperature. When delamination occurs within 2 hours using a process forming an insulating layer using the resin composition, the insulating layer was determined as a ‘poor’ layer. However, when delamination occurs after 2 hours using the process to form the insulating layer using the resin composition, the insulating layer was determined as a ‘good’ layer. Degassing stability is determined based on whether filler sedimentation or filler agglomeration occurred. When neither filler sedimentation nor filler agglomeration occurred, the degassing stability is determined as ‘O’. In turn, the degassing stability is determined as ‘X, XX, and XXX’ depending on an extent of occurrence of filler sedimentation or filler agglomeration. In case of ‘X and XX’, the degassing stability is used for manufacturing the insulating layer because the filler sedimentation or the filler agglomeration partially occurs or is partially present. In contrast, in case of ‘XXX’, the degassing stability may not be used because the filler sedimentation or the filler agglomeration occurs overall or is completely present.

TABLE 1

| | Particle size of | Filler sedimentation | Degassing |
|---|---|---|---|
| Sample No. | teflon resin (μm) | time(hr) | stability |
| Example 1 | 0.2 | 24 or more | ◯ |
| Example 2 | 0.3 | 24 or more | ◯ |
| Example 3 | 0.5 | 24 or more | ◯ |
| Example 4 | 2 | 24 or more | ◯ |
| Example 5 | 3 | 8 | X |
| Example 6 | 5 | 3 | XX |
| Comparative | 7 | 2 | XXX |
| Example 1 | | | |

According to Table 1, when a particle size of the teflon resin 3 is greater than 5 μm (Comparative Example 1), the filler sedimentation time is less than 2 hours and filler sedimentation or filler agglomeration occurs overall or is completely present during the degassing process, such that the teflon resin 3 cannot be used to manufacture the insulating layer.

The teflon resin 3 is used in an amount of 20 wt % to 50 wt % based on a total weight of the resin composition. When an amount of the teflon resin 3 is less than 20 wt %, the dissipation factor increases as a result of a low amount of the filler in the resin composition. On the other hand, when an amount of the teflon resin 3 is more than 50 wt %, dispersibility and miscibility of the teflon resin 3 deteriorates and the adhesion between the insulating layer, which is prepared using the resin composition, and the conductive circuit are reduced due to an excess of the filler in the resin composition. The amount of the teflon resin 3 included in the resin composition is 20 wt % to 50 wt %.

Dissipation factor, dispersibility and miscibility depending on the amount of the teflon resin 3 are summarized in Table 2, reproduced below. The epoxy resin and the hardening agent are the same as those in Table 1. A teflon resin 3 having a particle size of 2 μm is used as a filler and the teflon resin 3 is used in an amount of 10, 20, 30, 40, 50, 60 wt % when a total weight of the epoxy resin and the hardening agent is 100 wt %. The dissipation factor is determined using a resonance method and a value of 10 GHz is measured. The filler sedimentation time and the degassing stability are the same as described in Table 1.

TABLE 2

| | Amount of | Dissipation | Filler | |
|---|---|---|---|---|
| | teflon | factor | sedimentation | Degassing |
| Sample No. | resin(wt %) | (tangent δ) | time(hr) | stability |
| Comparative | 10 | 0.0055 | 12 | ◯ |
| Example 2 | | | | |
| Example 7 | 20 | 0.0050 | 8 | ◯ |
| Example 8 | 30 | 0.0049 | 5 | ◯ |
| Example 9 | 40 | 0.0048 | 4.5 | X |
| Example 10 | 50 | 0.0046 | 4 | X |
| Comparative | 60 | 0.0043 | 2 | XXX |
| Example 3 | | | | |

According to Table 2, when an amount of teflon resin 3 is less than 20 wt % (Comparative Example 2), the dissipation factor is greater than 0.005 tangent δ. When an amount of teflon resin 3 is more than 50 wt % (Comparative Example 3), the filler sedimentation time is 2 hours or less and filler sedimentation or agglomeration occurs during the degassing process, such that the teflon resin 3 cannot be used to prepare the insulating layer.

Nano-silica 4 particles are arranged on the surface of the teflon resin 3. The Nano-silica 4 used in an embodiment includes a particle size of 10 nm or less, but it is not limited thereto.

When the particle size of the nano-silica 4 is greater than 10 nm, surface energy of the teflon resin 3 does not increase enough to be dispersed well in the resin composition. Therefore, the particle size of the nano-silica 4 is 10 nm or less.

Dispersibility and miscibility depending on the particle size of the nano-silica 4 is summarized in Table 3, reproduced below. The epoxy resin and the hardening agent are the same as those in Table 1. A teflon resin 3 having a particle size of 2 μm is used as a filler and 50 wt % of the teflon resin 3 is used when a total weight of the epoxy resin and the hardening agent is 100 wt %. The filler sedimentation time and the degassing stability are the same as described in Table 1.

TABLE 3

| | Particle size of | Filler sedimentation |
|---|---|---|
| Sample No. | nano-silica(nm) | time(hr) |
| Comparative | 10 | 24 or more |
| Example 4 | | |
| Example 11 | 50 | 21 |
| Example 12 | 100 | 12 |

According to Table 3, when a particle size of nano-silica is 10 nm or less, the filler sedimentation time is 24 hours or more, resulting in good dispersibility.

The resin composition, according to an embodiment, also includes a silica filler 5. The silica filler 5 is used in an amount of 5 wt % to 20 wt % based on the total weigh of the resin composition.

When an amount of the silica filler 5 is more than 20 wt %, an amount of the total filler in the resin compositing is high. As a result, the silica remained after filling pores between the teflon filler particles deteriorates dispersibility and miscibility, increases the dissipation factor, and decreases adhesion strength between the layers. On the other hand, when an amount of the silica filler 5 is less than 5 wt %, such amount of the silica filler 5 may not be enough to fill pores between the teflon filler particles, causing a further reduction in the dissipation factor for low filling factor and lowering a coefficient of thermal expansion. Therefore, in an embodiment, the silica filler 5 is used in an amount of 20 wt % or less, preferably 5 wt % to 20 wt %, based on the total weight of the resin composition.

Dissipation factor, dispersibility, and miscibility depending on an amount of the silica filler is summarized in Table 4, reproduced below. The epoxy resin and the hardening agent are the same as those in Table 1. A teflon resin 3 has a particle size of 2 μm and includes nano-silica with a particle size of 10 nm or less on the surface. The teflon resin 3 is used as a filler. The teflon resin 3 and the silica filler are used in an amount of 50 wt % when a total weight of the epoxy resin and the hardening agent is 100 wt %. An amount of the silica filler is 0, 3, 5, 10, 20, 30 wt % to determine the properties.

Descriptions relating to the dissipation factor, the filler sedimentation time, and the degassing stability are identical to the description described with reference to Table 1 to Table 3.

TABLE 4

| | Amount of | Dissipation | Filler | |
|---|---|---|---|---|
| | silica | factor | sedimentation | Degassing |
| Sample No. | filler (wt %) | (tangent δ) | time(hr) | stability |
| Example 13 | 0 | 0.0046 | 12 | ◯ |
| Example 14 | 3 | 0.0040 | 8 | ◯ |
| Example 15 | 5 | 0.0032 | 5 | ◯ |
| Example 16 | 10 | 0.0038 | 4.5 | ◯ |
| Example 17 | 20 | 0.0045 | 3 | X |
| Comparative | 30 | 0.0046 | 1.7 | XXX |
| Example 5 | | | | |

According to Table 4, when an amount of the silica filler is more than 20 wt %, the filler sedimentation time is 2 hours or less and the filler sedimentation or the filler agglomeration occurs overall during the degassing process. As a result, the silica filler cannot be used for manufacturing the insulating layer.

The dissipation factor is improved in Examples 14-17 in which the silica filler is included, compared to Example 13 in which silica filler is not included as shown in Table 4. The dissipation factor is significantly improved when an amount of the silica filler is 5 wt % (Example 15), compared to when an amount of the silica filler is 3 wt % (Example 14). Therefore, the amount of the silica filler is 20 wt % or less, for example, 5 to 20 wt %.

The resin composition, according to an embodiment, further includes an inorganic filler, an organic filler, or a combination thereof, which is different from the filler described above.

An example of the inorganic filler includes at least one of alumina, aluminum nitride, boron nitride, melt silica, silicon nitride, and teflon, but it may not be limited thereto.

An example of the organic filler includes at least one of thermoplastic liquid crystal polymer resin, cellulose, carbon nanotube, graphene, and graphite, but it may not be limited thereto.

An amount of the inorganic and the organic filler is determined based on coefficient of thermal expansion, adhesion strength, and other similar factors of the insulating layer to be prepared using the resin composition.

The resin composition, according to an embodiment, further includes a hardening agent. In one illustrative example, the resin composition cross links with and hardens the epoxy resin 2. An example of the hardening agent includes a phenol-based hardening agent(phenol resin), a cyanate ester-based hardening agent, an active ester-based hardening agent, and other similar agents. The hardening agent reduces surface roughness of the insulating layer to be prepared using the resin composition.

Dissipation factors of the insulating layer prepared using the resin composition, according to an embodiment, and the insulating layer prepared using the resin composition, in which at least one component is deviated from the embodiment, are summarized in Table 5.

In Comparative Example 6, an epoxy resin including a bisphenol A type epoxy resin and an o-cresol novolac type(o-cresol novolac) epoxy resin mixed in 1:1 is used. An active ester(HPC-8000-65T, DIC Corp.) is used as a hardening agent. The epoxy resin and the hardening agent are mixed in an equivalent ratio of 1:1. Silica is used as a filler. Silica used as the filler (hereinafter, referred to as silica filler) is surface-treated with aminophenyl silane to have amine groups on the surface. The silica filler is used in an amount of 75 wt %, when a total weight of the epoxy resin and the hardening agent is 100 wt %. A phenoxy resin is used as a thermoplastic polymer, 4-dimethylaminopyridine(DMAP) is used as a hardening catalyst, and a PDMS-based leveling agent is used to improve surface properties of an insulating layer.

The epoxy resin, the hardening agent, the filler, and the other additives are combined uniformly and hardened through 3-stpes of a hardening process to produce the insulating layer.

In Comparative Example 7, the epoxy resin, the hardening agent, and the other additives, which are used in Comparative Example 6 are also used. The teflon resin 3 having a particle size of 2 μm is used as a filler in an amount of 50 wt % when a total weight of the epoxy resin and the hardening agent is 100 wt %. A process to prepare an insulating layer is the same as in Comparative Example 6. The teflon resin 3 is a pallet typed teflon resin including polytetrafluoroethylene (C₂F₄).

In Example 18, the epoxy resin, the hardening agent, and the other additives, which are used in Comparative Example 6 are also used in this example. The teflon resin 3 has a particle size of 2 μm and includes nano-silica having a particle size of 10 nm or less. On the surface, the teflon resin 3 is used as a filler in an amount of 50 wt % when a total weight of the epoxy resin and the hardening agent is 100 wt %. A process to prepare an insulating layer is the same as in Comparative Example 6. The teflon resin 3 is a pallet typed teflon resin 3 including polytetrafluoroethylene (C₂F₄). The teflon resin 3 is also surface-treated with nano-silica by hot melt mixing, crushing, and processing. The teflon resin 3 includes the nano-silica 4 on the surface thereof.

In Example 19, the hardening agent, the filler and the other additives, which are used in Comparative Example 6 are also used in Example 19. The teflon resin 3 has a particle size of 2 μm and includes nano-silica, having a particle size of 10 nm or less on the surface thereof, and a silica filler, having a particle size of 500 nm, are mixed and a mixture thereof is used as a filler. The mixture of the teflon resin 3 and the silica filler is used in an amount of 50 wt % when a total weight of the epoxy resin and the hardening agent is 100 wt %. A process to prepare an insulating layer is the same as in Comparative Example 6. The teflon resin 3 is a pallet typed teflon resin including polytetrafluoroethylene (C₂F₄). The teflon resin 3 is also surface-treated with nano-silica by hot melt mixing, crushing, and processing for the teflon resin 3 to include the nano-silica 4 on the surface thereof.

Dissipation factors are determined using a resonance method and a value of 10 GHz is measured. The result is summarized in the following Table 5.

TABLE 5

| Sample No. | Dissipation factor (tangent δ) |
|---|---|
| Comparative | 0.0073 |
| Example 6 | |
| Comparative | 0.0061 |
| Example 7 | |
| Example 18 | 0.0046 |
| Example 19 | 0.0032 |

According to Table 5, Comparative Examples 6 and 7, in which the teflon resin 3 does not include the silica filler and nano-silica on the surface thereof and is used as a filler, show the dissipation factor of greater than 0.005 tangent δ. On the other hand, Example 18, in which the teflon resin 3 includes nano-silica on the surface thereof and is used as a filler, shows the dissipation factor of 0.0046 tangent δ, which is lower than those in Comparative Examples 6 and 7. Example 19, in which the teflon resin 3 includes nano-silica on the surface thereof and the silica filler and are used as a filler, shows the lowest dissipation factor of 0.0032 tangent δ.

When the teflon resin 3 including nano-silica on the surface thereof is used as a filler, an insulating layer with the dissipation factor of 0.005 tangent δ or less is obtained. Furthermore, when the teflon resin 3 including nano-silica on the surface thereof and the silica filler are used as a filler, an insulating layer with the dissipation factor of 0.004 tangent δ or less is obtained.

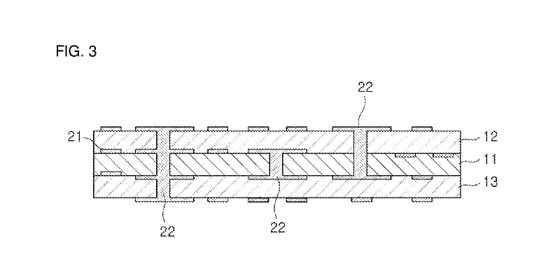

FIG. 3 is a sectional view schematically illustrating a printed circuit board, according to an embodiment.

Referring to FIG. 3, a printed circuit board, according to an embodiment, includes insulating layers 11, 12, 13 that are manufactured using the resin composition, according to an embodiment described above.

The resin composition includes an epoxy resin and a teflon resin 3 in which the teflon resin includes nano-silica on the surface thereof. A particle size of the nano-silica is 0.5 μm to 5.0 μm and an amount of the teflon resin 3 is 20 wt % to 50 wt % based on the total weight of the resin composition. The resin composition may further include a silica filler as a filler. An amount of the silica filler is 5 wt % to 20 wt %, based on the total weight of the resin composition. The resin composition may further include an ester hardening agent.

The insulating layer 11, 12, 13 used for the circuit board have a dissipation factor of 0.0050 tangent δ or less, for example, 0.0040 tangent δ or less.

Referring to FIG. 3, a printed circuit board, according to an embodiment, includes a first insulating layer to a third insulating layer 11, 12, 13 and a horizontal signal line 21 and a via electrode 22, which are formed on one surface or both surfaces of the first insulating layer to the third insulating layer 11, 12, 13. The first insulating layer 11 is prepared as a center layer and then the second insulating layer 12 and the third insulating layer 13 are formed on the upper surface and the lower surface of the first insulating layer 11, respectively, to be provided as a main board.

At least one horizontal signal line 21 is formed on one surface or both surfaces of the first insulating layer to the third insulating layer 11, 12, 13 and the via electrode 22 vertically passes through the insulating layers 11, 12, 13 to electrically connect each horizontal signal line 21.

A 4-Layered printed circuit board is shown in FIG. 3, but it is not limited thereto. A single layer or 2- or more-layered circuit board may be formed based on a number of the insulating layers and circuit patterns to be formed.

The insulating layers 11, 12, 13 of a printed circuit board is prepared using the resin composition, according to the various embodiments described above.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A resin composition, comprising:
an epoxy resin; and
a teflon resin comprising nano-silica on a surface thereof.

2. The resin composition of claim 1, wherein the teflon resin comprises a particle size of 5.0 μm or less.

3. The resin composition of claim 1, wherein the nano-silica comprises a particle size of 10 nm or less.

4. The resin composition of claim 1, wherein an amount of the teflon resin is 20 wt % to 50 wt %, based on a total weight of the resin composition.

5. The resin composition of claim 1, further comprising a silica filler.

6. The resin composition of claim 5, wherein an amount of the silica filler is 5 wt % to 20 wt %, based on a total weight of the resin composition.

7. The resin composition of claim 1, wherein an insulating layer comprising the epoxy resin and the teflon resin comprises a dissipation factor of 0.0050 tangent δ or less.

8. The resin composition of claim 1, wherein an insulating layer comprising the epoxy resin and the teflon resin comprises a dissipation factor of 0.0040 tangent δ or less.

9. The resin composition of claim 1, further comprising an ester hardening agent.

10. A printed circuit board, comprising:
an insulating layer comprising
an epoxy resin, and
a teflon resin comprising nano-silica on a surface thereof.

11. The printed circuit board of claim 10, wherein the insulating layer comprises a dissipation factor of 0.0050 tangent δ or less.

12. The printed circuit board of claim 10, wherein the insulating layer comprises a dissipation factor of 0.0040 tangent δ or less.

13. The printed circuit board of claim 10, wherein the teflon resin comprises a particle size of 5.0 μm or less.

14. The printed circuit board of claim 10, wherein the nano-silica comprises a particle size of 10 nm or less.

15. The printed circuit board of claim 10, wherein an amount of the teflon resin is 20 wt % to 50 wt %, based on a total weight of the resin composition.

16. The printed circuit board of claim 10, further comprising a silica filler.

17. A printed circuit board, comprising:
a first insulating layer formed as a center layer;
a second insulating layer formed on an upper surface of the first insulating layer;
a third insulating layer formed on a lower surface of the first insulating layer;
a horizontal signal line; and
a via electrode, wherein
the horizontal signal line and the via electrode are formed on at least one surface of the first insulating layer, the second insulating layer, and the third insulating layer,
the via electrode vertically passes through the insulating layers to electrically connect each horizontal signal line, and
at least one of the first insulating layer, the second insulating layer, and the third insulating layer comprises an epoxy resin and a teflon resin comprising nano-silica on a surface thereof.

18. The printed circuit board of claim 17, wherein the teflon resin comprises a particle size of 5.0 μm or less.

19. The printed circuit board of claim 17, wherein the nano-silica comprises a particle size of 10 nm or less.

20. The printed circuit board of claim 17, wherein an amount of the teflon resin is 20 wt % to 50 wt %, based on a total weight of the resin composition.
